(19) United States
(12) Patent Application Publication
(10) Pub. No.: US 2025/0300541 A1
(43) Pub. Date: Sep. 25, 2025

(54) TERMINAL FOR SUPERCONDUCTING WIRE, A SUPERCONDUCTING ROTARY MACHINE HAVING THE SAME, AND A METHOD FOR MANUFACTURING A TERMINAL

(71) Applicants: HYUNDAI MOTOR COMPANY, Seoul (KR); KIA CORPORATION, Seoul (KR)

(72) Inventors: Hoo Dam Lee, Seoul (KR); Tae Gyu Lee, Seoul (KR); Hyung Kwan Jang, Uijeongbu-si (KR); Jun Hyeok Choi, Suwon-si (KR); Byung Ho Min, Suwon-si (KR); Kyung Sik Choi, Seoul (KR)

(73) Assignees: HYUNDAI MOTOR COMPANY, Seoul (KR); KIA CORPORATION, Seoul (KR)

(21) Appl. No.: 18/919,112

(22) Filed: Oct. 17, 2024

(30) Foreign Application Priority Data
Mar. 21, 2024 (KR) 10-2024-0039393

(51) Int. Cl. H02K 55/04; H01F 6/04; H01F 6/06; H10N 60/01; H10N 60/20

(52) U.S. Cl. CPC H02K 55/04; H01F 6/04; H01F 6/06; H10N 60/0801; H10N 60/203

(57) ABSTRACT

A terminal for a superconducting wire, a superconducting rotary machine having the same, and a method for manufacturing the terminal may improve the cooling efficiency and reduce the weight of a superconducting rotary machine. The terminal may include a frame having a hollow portion and having an open surface formed on at least one side thereof and may include a superconductor filled in the hollow portion. An end of a superconducting wire may be coupled to at least the superconductor.

### CROSS-REFERENCE TO RELATED APPLICATION

This application claims the benefit of priority to Korean Patent Application No. 10-2024-0039393 filed on Mar. 21, 2024 in the Korean Intellectual Property Office, the disclosure of which is incorporated herein by reference in its entirety.

### TECHNICAL FIELD

The present disclosure relates to a terminal for a superconducting wire, a superconducting rotary machine having the same, and a method for manufacturing the terminal, which may improve cooling efficiency and reduce the weight of a superconducting rotary machine.

### BACKGROUND

For example, in a superconducting rotary machine, such as a superconducting motor or a superconducting generator, a superconductor with electrical resistance close to zero is used as a field coil, instead of a copper wire, as used previously. A field coil including a superconductor may be formed by winding a superconducting wire in a racetrack shape or a pancake shape.

The superconducting field coil may have a configuration in which a superconducting wire is wound around a bobbin several times and terminals are connected to an inner end and an outer end of the wound superconducting wire, respectively. In addition, in order to lower the temperature of the superconducting wire to a critical temperature, the superconducting field coil may be connected to a cooling system. Typically, a terminal is formed in the shape of a line or plate and is formed of a metallic material such as copper.

When a large current is applied to the superconducting field coil, the terminal formed of the metallic material, such as copper, generates heat. There may be a problem of heat loss of about 91% at 20 Kelvin (K) and an increase in a cooling load of a cooling system. Moreover, the metallic material has a high specific gravity, which may cause an increase in a weight of the superconducting rotary machine.

### SUMMARY

Aspects of the present disclosure are to provide a terminal for a superconducting wire, a superconducting rotary machine having the same, and a method for manufacturing the terminal, each of which may improve cooling efficiency and reduce a weight of a superconducting rotary machine.

A terminal according to the present disclosure may include a frame having a hollow portion and having an open surface formed on at least one side thereof. The terminal may also include a superconductor filled in the hollow portion. An end of a superconducting wire may be coupled to at least the superconductor.

The superconductor may be formed by mixing a superconducting material and a binder to form a paste. The pasted superconducting material may then be filled into the hollow portion and the pasted superconducting material may be cured.

The superconducting material may include rare earth barium copper oxide.

The superconducting material may include at least one of rare earth metals of yttrium (Y), gadolinium (Gd), neodymium (Nd), samarium (Sm), or dysprosium (Dy).

The end of the superconducting wire may be impregnated with the paste, after which the paste may be cured and bonded.

The frame may be formed of a non-magnetic metal or alloy.

When the open surface faces upwardly, an opening may be formed on one side of a side wall towards a side of the frame.

A conductor may be added to the opening.

The conductor may be formed by filling an additional paste of a conductive metal material into the opening and curing the additional paste.

A surface roughness of an inner surface of the hollow portion may range from a roughness average (Ra) of 0.5 to 1.0 micrometers (μm).

A depth from the open surface in the hollow portion may range from 50 μm to 5 mm.

A superconducting rotary machine according to the present disclosure may include a rotor having a plurality of superconducting field coils arranged in a circumferential direction of a rotor core. The superconducting field coil may include a bobbin, a superconducting wire wound on the bobbin, and the above-described terminal connected to an end of the superconducting wire.

The superconducting field coil may further at least include an outer cover configured to cover a radial outer side.

A method for manufacturing a terminal may include preparing a frame having a hollow portion, preparing a paste including a superconducting material, and filling the paste into the hollow portion and curing the paste to form a superconductor.

The paste may be formed by mixing rare earth barium copper oxide with a binder. A weight ratio of the binder and the rare earth barium copper oxide may be 1:10.

The paste may have a viscosity ranging from 50, 000 to 1, 000,000 centipoise (cP) at a temperature of 25° C., at a humidity of 65%, and at atmospheric pressure.

The method for manufacturing a terminal may further include heat treating the frame filled with the paste.

The method for manufacturing a terminal may further include adding a conductor to an opening formed in a side wall of the frame.

Adding the conductor may include filling an additional paste of a conductive metal material into the opening and curing the additional paste.

The method for manufacturing a terminal may include, before curing the paste, impregnating an end of a superconducting wire with the paste.

According to an example embodiment of the present disclosure, there is no resistance by forming at least a portion of a terminal with a superconductor. Thus, when a large amount of current is applied, heat generation may be significantly reduced. A cooling load of a cooling system is thereby reduced, and the cooling efficiency of the superconducting rotary machine is thereby improved.

Additionally, according to an example embodiment of the present disclosure, heat loss accompanying heat generation may be reduced, resulting in the effect of minimizing power consumed in a field coil.

Additionally, according to an example embodiment of the present disclosure, the weight of not only a terminal but also a superconducting rotary machine may be reduced using a superconductor which has a lower specific gravity and is much lighter than a metallic material.

### BRIEF DESCRIPTION OF DRAWINGS

The above and other aspects, features, and advantages of the present disclosure should be more clearly understood from the following detailed description, taken in conjunction with the accompanying drawings, in which:

FIG. 1 is a perspective view illustrating a rotor to which a terminal according to the present disclosure is applied;

FIG. 2 is an enlarged perspective view illustrating one of the field coils of the rotor or FIG. 1;

FIG. 3 is a perspective view illustrating a terminal according to the present disclosure;

FIG. 4 is a flowchart illustrating a method for manufacturing a terminal according to the present disclosure; and

FIGS. 5, 6A, and 6B are perspective views illustrating mobility devices in which a superconducting rotary machine according to the present disclosure may be applied as a superconducting motor.

### DETAILED DESCRIPTION

Hereinafter, the present disclosure is described in detail with reference to the accompanying drawings. In adding reference numerals to elements of each of the drawings, although the same elements are illustrated in other drawings, like reference numerals may refer to like elements.

When a component, device, unit, element, or the like of the present disclosure is described as having a purpose or performing an operation, function, or the like, the component, device, unit, element, or the like should be considered herein as being “configured to” meet that purpose or to perform that operation or function.

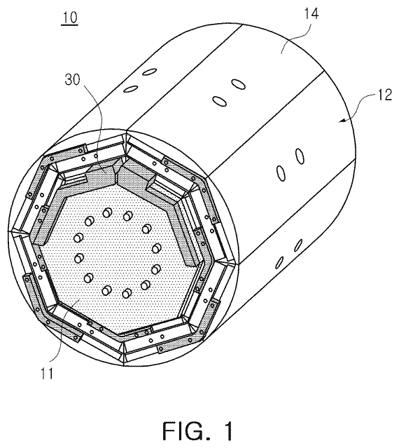

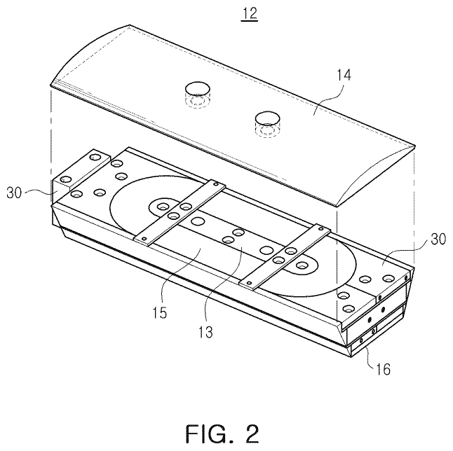

FIG. 1 is a perspective view illustrating a rotor to which a terminal according to the present disclosure is applied. FIG. 2 is an enlarged perspective view illustrating one field coil of the rotor of FIG. 1.

For example, a superconducting rotary machine, such as a superconducting motor or a superconducting generator, may include a rotor 10 and a stator (not illustrated). A superconducting rotary machine may be formed by surrounding a stator provided with an armature, on the outside of the rotor, provided with a superconducting field coil 12. The superconducting rotary machine may generate rotational force (motor) or electric power (generator) together with the stator when the rotor rotates.

In this specification, an example in which the terminal 20 according to the present disclosure is applied to a superconducting field coil 12 of the rotor 10 is mainly illustrated and explained. However, an application example of the present disclosure is not necessarily limited thereto, and when a stator armature coil uses a superconducting wire, the terminal 20 may also be applied to the stator.

The rotor 10 of the superconducting rotary machine may include a rotor core 11 and a plurality of superconducting field coils 12 arranged in a circumferential direction of the rotor core.

The rotor core 11 may be coupled to an axially extending shaft (not illustrated) in or near a radial center thereof. For this purpose, a hole for coupling the shaft may be formed in the radial center of the rotor core. However, a coupling method between the rotor core and the shaft is not necessarily limited to the above-described examples. For example, shafts may be fixedly coupled to the centers of both end surfaces of the rotor core without holes.

A plurality of coupling portions (not illustrated) may be formed on an outer peripheral surface of the rotor core 11 at predetermined intervals in the circumferential direction to mount and support the superconducting field coil. The coupling portion may be molded integrally with the rotor core or may be manufactured separately and assembled to the rotor core.

For example, each of the coupling portions may be formed to protrude radially from the rotor core 11 and be fitted and coupled to the bobbin 13 of the superconducting field coil 12. However, the shape of the coupling portion is not necessarily limited thereto. The coupling portion may be provided in the form of a flat surface supporting the superconducting field coil or a groove accommodating a portion of the bobbin.

The superconducting field coil 12 may include a bobbin 13, a superconducting wire 15 wound around the bobbin, and a terminal 30 connected to an end of the superconducting wire.

The bobbin 13 may serve as a support for winding the superconducting wire 15 and may form a magnetic flux path carrying magnetic flux. The bobbin 13 may have a shape such as a cylindrical shape, a square cylinder shape, or an oval shape. In FIG. 2, a bobbin 13 having an oval shape, i.e., a racetrack shape, is illustrated in which a straight portion is longer than a curved portion.

The superconducting wire 15 may be wound around the bobbin 13. The terminal 30 may be connected to both ends of the superconducting wire, for example, an inner end and an outer end. The superconducting wire may be physically and/or electrically connected to a power source (not illustrated) via the terminal. Accordingly, a large amount of current may be applied to the superconducting field coil.

For example, the superconducting wire 15 may be wound around the bobbin 13 in a pancake shape having at least one layer. Depending on a device to which the superconducting rotary machine is applied, the superconducting wire may be wound on the bobbin in a single layer or in multiple even layers.

In a state in which the superconducting field coil 12 is coupled to the coupling portion of the rotor core 11, the superconducting field coil and the coupling portion may form one pole. The rotor 10 illustrated in FIG. 1 has, for example, eight poles.

When a large amount of current is applied to the superconducting wire 15 from a power source, a magnetic field may be formed in the superconducting field coil 12. In other words, a large amount of current may be supplied to the superconducting wire so that the superconducting field coil may become a superconducting magnet.

Optionally, the superconducting field coil 12 may include an outer cover 14 configured to cover a radial outer side to protect components thereof. The outer cover 14 may be coupled to the bobbin, for example by use bolts or other fasteners. Additionally, the superconducting field coil may further include an inner cover 16 configured to cover a radial inner side and be coupled to the bobbin 13.

In this manner, the rotor 10 provided with the superconducting field coil 12 may be cooled to extremely low temperature by a cooling system (not illustrated) because the rotor 10 uses a superconductivity phenomenon, and may be accommodated into a vacuum chamber for insulation from the outside. Here, the vacuum chamber may be interposed between the rotor and the stator and may surround the rotor.

In order to lower a temperature of the superconducting wire 15 to a critical temperature, the superconducting field coil 12 may be connected to a cooling system. A refrigerator of the cooling system may be provided separately outside the rotary machine, or may be mounted in the rotor 10 and/or the vacuum chamber. In this case, the refrigerator may supply and recover liquid or gaseous refrigerant to the rotor and circulate the refrigerant. Since various cooling systems have been proposed to cool the superconducting rotary machine to cryogenic temperatures, a detailed description thereof has been omitted in this specification.

The rotor 10 of the superconducting rotary machine configured as described above may be installed to be rotatable by having a shaft coupled to the rotor core 11 and by supporting the shaft and the rotor by one or more bearings.

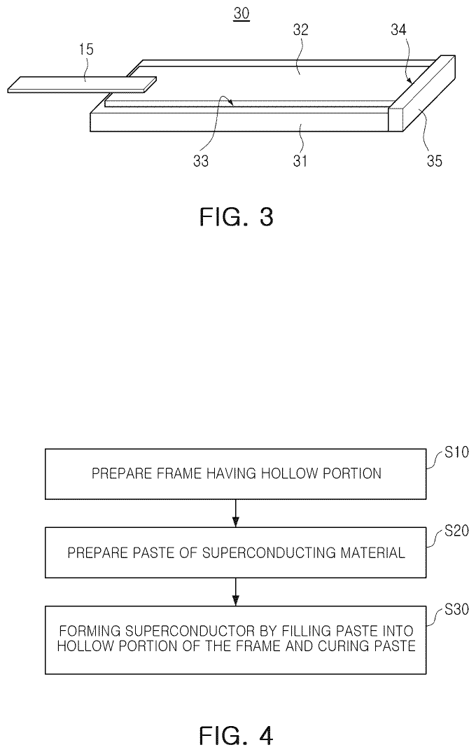

FIG. 3 is a perspective view illustrating a terminal according to the present disclosure.

The terminal 30 according to the present disclosure is configured in that at least a portion thereof is formed of a superconductor. For this purpose, the terminal according to the present disclosure may include a frame 31 and a superconductor 32.

The frame 31 may be formed in a box-like shape in which at least one side surface thereof is open and may include a hollow portion 33 and an open surface. FIG. 3 illustrates an example in which a frame has a roughly square or rectangular cross-sectional shape. However, the present disclosure is not necessarily limited thereto, and the frame may have a cross-sectional shape of any polygonal shape or an oval shape, for example.

This frame 31 may be formed of at least one material that does not have magnetic properties, such as hastelloy, austenitic stainless steel, or an aluminum-magnesium (Al—Mg) alloy.

Optionally, when the open surface faces upwardly, an opening 34 may be formed on a side wall toward a side of the frame 31. In this case, the opening may form a connection portion for connecting a power line to the superconductor 32. Additionally, when the open surface faces upwardly, a groove penetrating through the side wall may be formed on the other side of the opening.

The superconductor 32 may be filled in the hollow portion 33 of the frame 31 and may be exposed to the outside through the open surface. The superconductor may be formed by mixing and pasting rare-earth barium copper oxide (hereinafter referred to as REBCO) and a binder and then filling a pasted superconducting material into the hollow portion of the frame and curing the pasted superconducting material.

Here, REBCO may include at least one of rare earth metals such as yttrium (Y), gadolinium (Gd), neodymium (Nd), samarium (Sm), dysprosium (Dy), or any combination thereof.

Examples of specific types of binders for pasting the REBCO are not limited. Various widely known polymer resins, organic solvents, inorganic solvents, aqueous solvents, and the like, may be used as binders.

More specifically, the binder may include, for example, one or more selected from the group comprising or consisting of polystyrene, o-xylene, dichloromethane, acrylic resin, butyl acetate, x-terpineol, carboxymethyl cellulose sodium salt, or epoxidized soybean oil.

By mixing the REBCO with the binder, a paste for forming the superconductor may be prepared. For example, the binder may be included in an amount of about 1 to 10 weight percent (wt %), and a weight ratio of the binder and the REBCO may be approximately 1:10.

The prepared paste may have a viscosity ranging from approximately 50,000 to 1,000,000 cP at a temperature of 25° C., at a humidity of 65%, and at atmospheric pressure. In one example, the prepared paste may have a viscosity of about 100,000 to 500,000 cP.

A surface roughness of an inner surface of the frame 31 to which the paste is attached, especially the hollow portion 33, may range from Ra 0.5 to 1 μm. When the surface roughness of the frame is less than Ra 0.5 μm, the paste is not firmly attached to the frame, and conversely, when the surface roughness of the frame exceeds Ra 1 μm, a thickness of the paste attached to the frame becomes uneven, which may make it difficult to secure uniform magnetic flux.

Additionally, a depth from the open surface of the hollow portion 33 inside the frame 31 into which the paste is impregnated may range from 50 μm to 5 mm. Adhesion between the paste and the frame depends on a particle size of a composition, a viscosity of the paste, and the like, but when a depth of the hollow portion is formed to be smaller than 50 μm, it may be difficult for the paste to flow in, which increases the probability that an empty space or pores exist in the hollow portion, and thus firm attachment may not be ensured. On the other hand, when the depth of the hollow portion exceeds 5 mm, as the thickness of the paste increases, the superconductor 32 may become brittle, which may lead to the risk in that the superconductor may be easily broken by external shock.

In this manner, the terminal 30 according to the present disclosure may be comprised of at least a portion of the superconductor 32 by utilizing the paste formed of a superconducting material. Here, because the superconductor has reduced mechanical strength basically based on a ceramic material, the frame 31 having a hollow portion 33 may added to maintain a shape of the superconductor and supplement the strength thereof, so that the terminal may stably exhibit superconducting properties.

The superconductor 32 formed by curing the paste may have a significantly lower critical current than a thin-film superconducting wire. However, due to the properties of the paste, the superconductor 32 is not limited to the shape manufactured like, for example, a thin film, and the superconductor and the terminal 30 provided therewith may have the advantage of being able to be formed into various shapes and manufactured to a desired size.

Optionally, the terminal 30 according to the present disclosure may have a conductor 35 added to the opening 34 formed in the side wall of the frame 31. The conductor may be formed of a paste of a highly conductive metal material, such as copper.

When connecting the power line to the terminal 30 through the opening 34 of the frame 31, the superconductor 32 formed by curing the paste may be broken, and contact resistance thereof may increase. To solve this problem, after curing and completion of the superconductor, the conductor 35 may be formed in the opening on one side of the side wall of the frame by filling and curing a metal paste into the opening of the frame.

With this configuration, the superconductor 32 and the conductor 35 may be physically and electrically connected, and the power line may be connected to the conductor, thereby reinforcing the strength of the end of the superconductor as well as minimizing contact resistance.

The conductor 35 is not necessarily limited to being formed from paste, and any metal wire may be adopted as a conductor and bonded by soldering or the like.

On the other side of the opening 34, the end of the superconducting wire 15 of the superconducting field coil 12 may pass through the side wall of the frame 31 and may be impregnated with the paste forming the superconductor 32. For this purpose, a groove into which the superconducting wire may be inserted may optionally be formed on the other side of the opening. After the end of the superconducting wire is impregnated with the paste, as the paste is cured, the superconductor and the superconducting wire may be physically fixedly connected and electrically stably connected.

However, the connection between the superconducting wire 15 and the superconductor 32 is not necessarily limited thereto, and after the paste is cured, the end of the superconducting wire may be bonded to the superconductor by soldering or the like.

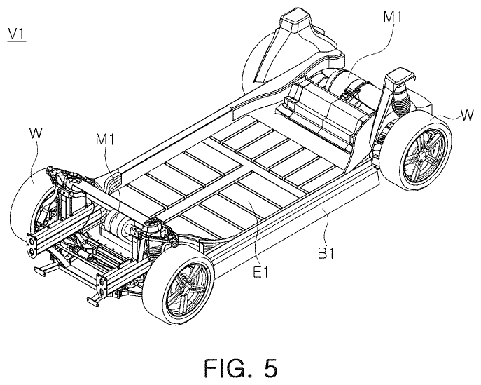

FIG. 4 is a flowchart illustrating a method for manufacturing a terminal according to the present disclosure.

A method for manufacturing a terminal 30 according to the present disclosure may include: an operation of preparing a frame 31 having a hollow portion 33 (S10); an operation preparing a paste including a superconducting material (S20); and an operation of forming a superconductor 32 by filling a paste into the hollow portion of the frame and curing the paste (S30).

As described above, the frame 31 may be formed and prepared in a box-like shape in which at least one side thereof is open using at least one material that does not have magnetic properties, such as hastelloy, austenitic stainless steel, or Al—Mg alloy (S10).

The paste may be formed and prepared by mixing a superconducting material with a binder (S20).

REBCO may be used as the superconducting material, and the REBCO may include at least one of rare earth metals such as yttrium (Y), gadolinium (Gd), neodymium (Nd), samarium (Sm), and dysprosium (Dy).

Additionally, the binder may include one or more selected from the group consisting of, for example, polystyrene, o-xylene, dichloromethane, an acrylic resin, butyl acetate, α-terpineol, carboxymethyl cellulose sodium salt, and epoxidized soybean oil.

By mixing the REBCO with the binder, a paste for forming the superconductor 32 may be produced. For example, the binder may be included in an amount of about 1 to 10 wt %, and a weight ratio of the binder and the REBCO may be approximately 1:10.

The prepared paste may have a viscosity ranging from about 50,000 to 1,000,000 cP at a temperature of 25° C., at a humidity of 65%, and at atmospheric pressure. In one example, the prepared paste may have a viscosity of about 100, 000 to 500, 000 centipoise (cP).

Next, the superconductor 32 of the terminal 30 may be formed by filling the paste including the superconducting material into the hollow portion 33 of the frame 31 and curing the paste (S30).

Optionally, the method for manufacturing a terminal according to the present disclosure may further include an operation of heat treating the frame 31 filled with the paste.

By slowly heating the terminal 30 filled with the paste to evaporate the binder in the paste by thermal decomposition, the binder may be removed, and curing of the paste, i.e., the superconductor 32, may be promoted. Because a heat treatment temperature and time may be appropriately set depending on the type of binder, the temperature and time is not particularly limited in this specification.

Optionally, the method for manufacturing a terminal according to the present disclosure may further include an operation of adding a conductor 35 to an opening 34 formed on a side wall of the frame 31.

For example, after the superconductor 32 is formed, the opening 34 of the frame 31 is filled with another paste, i.e., a metal paste and the metal paste is cured. The conductor 35 is thereby formed in the opening on one side of the side wall of the frame. However, the conductor is not necessarily limited to being formed from the paste, and any metal wire may be selected as a conductor and bonded by soldering or the like.

Finally, the method for manufacturing a terminal according to the present disclosure may include an operation of impregnating an end of the superconducting wire 15 included in a superconducting field coil 12 with the paste. The end of the superconducting wire may pass through the side wall of the frame 31, and may be impregnated into the paste forming the superconductor 32. To this end, a groove may be formed on the other side of the opening 34 in the frame, but the present disclosure is not necessarily limited thereto.

As described above, according to an example embodiment of the present disclosure, there is no resistance by forming at least a portion of the terminal with a superconductor. Thus, when a large amount of current is applied, heat generation may be significantly reduced. A cooling load on a cooling system is thereby reduced and the cooling efficiency of the superconducting rotary machine is thereby improved.

Additionally, according to an example embodiment of the present disclosure, heat loss accompanying heat generation may be reduced, resulting in the effect of minimizing power consumed in the field coil.

Additionally, according to an example embodiment of the present disclosure, the weight of the terminal as well as the superconducting rotary machine may be reduced using a superconductor, which has a lower specific gravity and is much lighter than a metallic material.

Meanwhile, a superconducting rotary machine provided with a terminal for a superconducting wire according to the present disclosure may be used as a superconducting motor. Hereinafter, application examples thereof are briefly described.

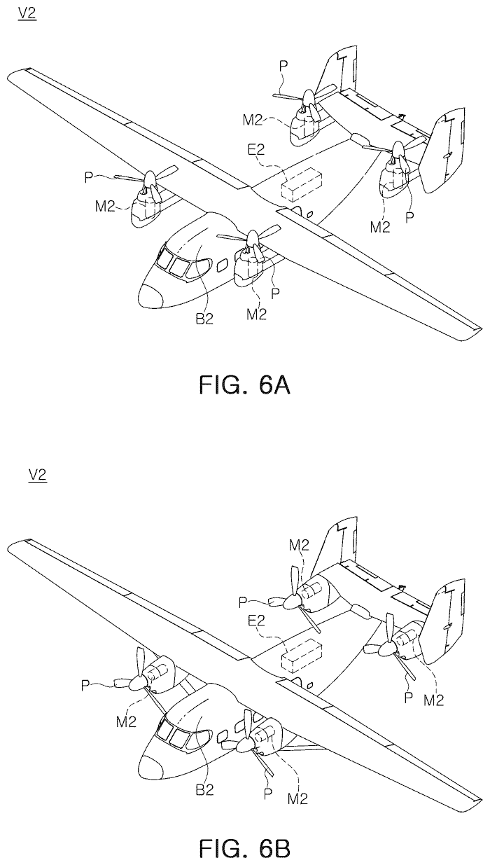

FIGS. 5, 6A, and 6B are perspective views illustrating mobility devices or vehicles in which a superconducting rotary machine according to the present disclosure may be applied as a superconducting motor.

Mobility devices V1 and V2 may at least include bodies B1 and B2, driving means W and P provided in the bodies B1 and B2, superconducting motors M1 and M2 linked to the driving means W and P, and batteries E1 and E2 configured to provide power to the superconducting motor. The superconducting motors M1 and M2 installed in the mobility devices V1 and V2 may have the configuration of the superconducting rotary machine described above.

Referring to FIG. 5, the mobility device V1 may be a vehicle that may be movable on the ground. The vehicle may at least include a body B1, a wheel that is a driving means W provided on the body B1, a superconducting motor M1 linked to the driving means W, and a battery E1 configured to provide power to the superconducting motor.

Additionally, referring to FIGS. 6A and 6B, the mobility device V2 may be an air mobility device that moves or flies in the air. The air mobility device may at least include a body B2, a propellant (e.g., a propeller) as the driving means P provided on the body B2, a superconducting motor M2 linked to the propellant, and a battery E2 configured to provide power to the superconducting motor.

FIG. 6A illustrates a position of the propellant when the air mobility device takes off, lands, or hovers for turning at a specific point. FIG. 6B illustrates a position of the propellant when the air mobility device moves through the air, i.e., when the air mobility device operates or flies. In other words, the propeller, which is the driving means P of the air mobility device, may be provided with a structure in which a direction in which the propeller faces may be tilted. The superconducting motor M2 that drives the propellant may also be tilted accordingly.

For a hovering mode illustrated in FIG. 6A, the propellants of main and/or tail wings are turned to be substantially perpendicular to the body B2. For an operating mode illustrated in FIG. 6B, the propellants of the main and/or tail wings may be turned to be substantially parallel to a longitudinal axis of body B2. Tilting of the propellants of the main and/or tail wings may be synchronized depending on a flight mode. Alternatively, tilting of each propellant may be adjusted differently depending on attitude control and flight conditions in the same flight mode.

Meanwhile, specific illustration has been omitted, but the mobility device may be a device that moves in a space, such as on land, underground, in the air, in space, at sea, and/or underwater, depending on the space in which the mobility device is designed and intended to move. Above-ground or underground mobility devices may be provided in the form of, for example, a vehicle, a robot, or the like.

Mobility devices in the air and space are aerial mobility devices and may be provided, for example, in the form of a conventional fixed-wing or rotary-wing aircraft, a tilt-rotor aircraft, a vertical takeoff and landing aircraft, an unmanned aerial vehicle, or a moving means mounted on a drone, a rocket, or an artificial satellite. The maritime or underwater mobility devices may be provided as, for example, a ship, a submarine, or the like. The mobility device is not limited to a specific space and may be a mobile body that may be movable through all of the above-mentioned spaces, i.e., a mobile body that may be moved to multiple spaces, and may be, for example, an amphibious vehicle, a flying vehicle, or the like.

The aforementioned description merely illustrates the technical concept of the present disclosure. A person of ordinary skill in the art to which the present disclosure pertains may make various modifications and alterations without departing from the essential characteristics of the present disclosure.

Therefore, the example embodiments disclosed in this specification and drawings are not intended to limit the scope of the disclosure, but instead to explain the technical concepts of the present disclosure. The scope of the technical ideas of the present disclosure is not limited by these example embodiments. The scope of protection of the present disclosure should be interpreted by the following claims, and all technical ideas within the scope equivalent thereto should be interpreted as being included in the scope of the present disclosure.

What is claimed is:

1. A terminal comprising:
a frame having a hollow portion and having an open surface formed on at least one side thereof; and
a superconductor in the hollow portion,
wherein an end of a superconducting wire is coupled to at least the superconductor.

2. The terminal according to claim 1, wherein the superconductor includes a superconducting material and a binder, wherein the superconductor is disposed in the hollow portion, and wherein the superconductor is cured.

3. The terminal according to claim 2, wherein the superconducting material includes rare earth barium copper oxide.

4. The terminal according to claim 2, wherein the superconducting material includes at least one of rare earth metals of yttrium (Y), gadolinium (Gd), neodymium (Nd), samarium (Sm), dysprosium (Dy), or any combination thereof.

5. The terminal according to claim 2, wherein the end of the superconducting wire is impregnated with the superconducting material, which is cured and bonded.

6. The terminal according to claim 1, wherein the frame is formed of a non-magnetic metal or alloy.

7. The terminal according to claim 1, wherein, when the open surface faces upwardly, an opening is formed on one side of a side wall towards a side of the frame.

8. The terminal according to claim 7, wherein a conductor is provided at the opening.

9. The terminal according to claim 8, wherein the conductor includes an additional paste of a conductive metal material in the opening, and wherein the paste is cured.

10. The terminal according to claim 1, wherein a surface roughness of an inner surface of the hollow portion ranges from roughness average (Ra) of 0.5 to 1.0 micrometers (μm).

11. The terminal according to claim 1, wherein a depth from the open surface in the hollow portion ranges from 50 μm to 5 mm.

12. A superconducting rotary machine includes a rotor having a plurality of superconducting field coils arranged in a circumferential direction of a rotor core, the superconducting field coil comprising:
a bobbin;
a superconducting wire wound on the bobbin; and
a terminal connected to an end of the superconducting wire, the terminal including
a frame having a hollow portion and having an open surface formed on at least one side thereof, and
a superconductor filled in the hollow portion,
wherein an end of the superconducting wire is coupled to at least the superconductor.

13. The superconducting rotary machine according to claim 12, wherein the superconducting field coil further includes at least an outer cover configured to cover a radial outer side.

14. A method comprising:
preparing a frame having a hollow portion;
preparing a paste including a superconducting material; and
filling the paste into the hollow portion and curing the paste to form a superconductor.

15. The method according to claim 14, wherein the paste is formed by mixing rare earth barium copper oxide with a binder, and wherein a weight ratio of the binder and the rare earth barium copper oxide is 1:10.

16. The method according to claim 14, wherein the paste has a viscosity ranging from 50,000 to 1,000,000 centipoise (cP) at a temperature of 25° C., at a humidity of 65%, and at atmospheric pressure.

17. The method according to claim 14, further comprising:
heat treating the frame filled with the paste.

18. The method according to claim 14, further comprising:
adding a conductor to an opening formed in a side wall of the frame.

19. The method according to claim 18, wherein adding the conductor includes filling an additional paste of a conductive metal material into the opening and curing the additional paste.

20. The method according to claim 14, comprising:
before curing the paste, impregnating an end of a superconducting wire with the paste.
